(19) United States
(12) Patent Application Publication
(10) Pub. No.: US 2012/0079348 A1
(43) Pub. Date: Mar. 29, 2012

(54) DATA WITH APPENDED CRC AND RESIDUE VALUE AND ENCODER/DECODER FOR SAME

(76) Inventor: Helia Naeimi, Santa Clara, CA (US)

(21) Appl. No.: 12/890,513

(22) Filed: Sep. 24, 2010

(51) Int. Cl. H03M 13/05; G06F 11/10

(52) U.S. Cl. 714/763; 714/E11.034

(57) ABSTRACT

A semiconductor chip is described having ECC decoder circuitry disposed along any of: i) an interconnect path that resides between an instruction execution core and a cache; ii) an interconnect path that resides between an instruction execution core and a memory controller; and, iii) an interconnect path that resides between a cache and a memory controller. The ECC decoder circuitry has an input register to receive data, CRC values associated with the data and residue information associated with the data.

### FIELD OF INVENTION

The field of invention relates generally to computing system design, and, more specifically to a computing system having data with appended CRC and residue value and encoder/decoder for the same.

### BACKGROUND

Computing systems process information. In order to properly process information, the underlying information should be correct or free of errors. As such, schemes exist in the art to identify “bad” data or data that has otherwise been corrupted in some way. In the case of Cyclic Redundancy Check (CRC) schemes, a CRC value is generated from the data itself and appended to the data. With the appended CRC value, the integrity of the data can be checked by recalculating the CRC value from the data and comparing it against the appended CRC value. If there is a mismatch the data may have been corrupted.

An issue in known computing systems is that reside values are not appended to data as it moves through the computing system. A residue can be used to detect an error and can be calculated by dividing the value of the data by a number and determining the integer remainder from the division. FIG. 1 shows a typical example in which data 101 having appended CRC 102 resides in a memory 103. The data 101 may be needed by a processor 104 and therefore is read from memory 103 (e.g., by a memory controller 105). The data is eventually processed by an instruction execution pipeline 106 within the processor 104. According to a known approach, the CRC is used to correct any error that could have happened in the memory system. Then just prior to being processed by the pipeline 106 (that is, in preparing the data for the pipeline), a residue for the data is calculated by residue calculation unit 110 and the calculated residue are used to determine if the data in the pipeline would encounter any error during the execution.

Along the interconnect path 107 to the memory path 103 to the residue calculation unit 110 just before the pipeline 106 there are a number of locations where the data may become corrupted. For instance, interconnect path 107 shows the existence of buffers 108a,b,c into which the data and appended CRC is queued en route to the pipeline 106.

Error Correction Codes (ECCs) go the further step of trying to correct an error once it has been discovered. One challenging problem regarding usage of codes for error detection/correction in the processor, memory 103 and interconnect path 107 is that different types of codes are used. For example, error correction codes (ECC) such as Hamming codes or similar codes can be used in the memory 103, and error detection codes such as residual arithmetic codes can be used along the pipeline stages 106 and various parity codes are used in many control logic areas and interconnect path 107. The problem with using different types of codes in different areas of the system is that the data needs to be encoded and decoded multiple times when flowing through the system, increasing power consumption, complexity and real estate costs. Furthermore the circuits at the boundary of two ECC domains, which performs the encoding and decoding, will not have any coverage.

Therefore moving data from one part of the system to another part requires the data going through unprotected regions. Moving the data in the system also requires extra encoding and decoding. The extra decoding and encoding process at the boundary of each sub-block increases the latency and power consumption, and also reduces the coverage (since the encoding an decoding process can introduce errors to the data as well). As a result, this patchwork solution increases the design complexity of the system, and causes a processor or system-on-a-chip (SoC) design to be more challenging.

Moreover, heretofore, ECCs are not know to have used a residue value to correct an error.

### BRIEF DESCRIPTION OF THE DRAWINGS

The present invention is illustrated by way of example and not limitation in the figures of the accompanying drawings, in which like references indicate similar elements and in which:

FIG. 1 shows a prior art computing system and datapath;

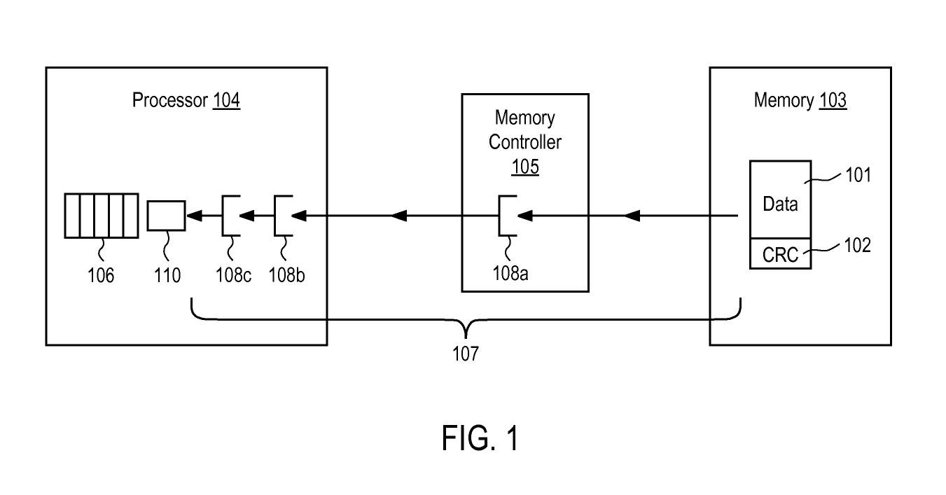

FIG. 2 shows an improved computing system and datapath;

FIG. 3 shows an encoding process;

FIG. 4 shows a decoding process;

FIG. 5 shows an error correction process; and,

FIG. 6 shows a circuit design of a decoder;

FIG. 7 shows a circuit design of an encoder;

FIG. 8 shows a diagram of a computing system.

### DETAILED DESCRIPTION

In various embodiments, an end-to-end coding technique may be used that covers a complete system, and replaces multiple different coding techniques with a single code. As described herein, in an embodiment, such a code includes a CRC code that uses reside information to correct an error and that may be used to provide end-to-end coverage for many different system structures.

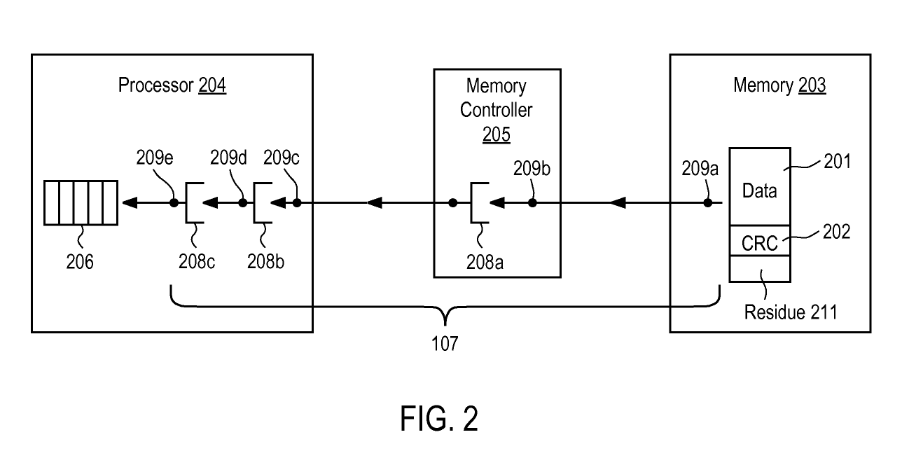

FIG. 2 shows an improved system that provides ECC coverage at various points 209a,b,c,d,e along the interconnect path 207 between memory 203 and a processor's instruction execution core 206 (such as an instruction pipeline). A number of these points include areas proximate to buffers 208a,b,c. In an embodiment, the CRC operations that occur at point 209a use an error correcting code algorithm that uses residue information to correct an error as described further below. An artifact of the ECC algorithm is that the residue value used by the algorithm is appended to the data. In the improved system of FIG. 2 both CRC 202 and residue 211 are appended to data 201. After the data 201 is read from memory 203, the CRC 202 and the residue 211 is used to correct any potential error in the memory system. The appended residue 211 travels with the data 201 along the interconnect path 207 to the instruction execution core 206.

In an embodiment, the data is ECC encoded before it is written to memory 203. The ECC encoding process creates the CRC 202 and reuse the residue values 211 which comes from the execution unit 206 and are appended to the data 201. The encoding process can take place in various locations such as, to name a few, the memory controller 205 (e.g., along its write data path), or, the processor 204 after the data has been created by the execution core 206 (e.g., along or within a datapath the flows from the write back stage of an execution pipeline), or, a cache controller (not shown, e.g., along its write data path).

Although the data being encoded may be created by the processor (as alluded to above) it may also be created elsewhere and therefore encoded elsewhere. For instance the data may be received through a networking interface (not shown) and stored in memory 203 (and/or a cache). Alternatively, the data may come from a non volatile storage device such as a hard disk drive or CD drive (also not shown). As such, it is pertinent to point out that the data may be encoded in any of a number of different places.

Likewise, decoders used to perform error correction according to the algorithm described below may also be located along various interconnect paths besides the interconnect path 207 observed between memory 203 and instruction execution core 206. For instance, at least one decoder may be located along any of: i) interconnect path from a cache to circuitry 210 or pipeline 206; ii) a interconnect path from a cache to memory 203; iii) a interconnect path from memory 203 to a cache; iv) a interconnect path from memory 203 to circuitry 210 or pipeline 206; v) a interconnect path from a networking interface to memory 203; vi) a interconnect path from a non volatile storage device to memory 203. It is also pertinent to point out that the encoder(s) and/or decoder(s) themselves may be implemented in software as program code that is executed on some kind of processing core (such as an embedded processor or microcontroller), semiconductor logic circuitry or a combination of the two.

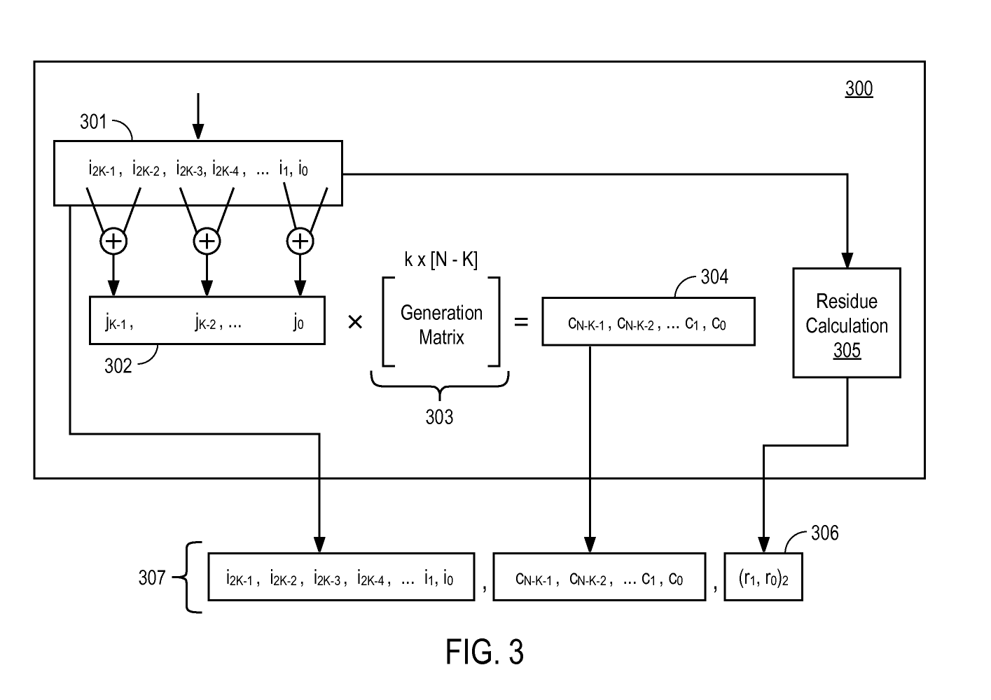

FIG. 3 shows an encoding process 300. The data to be encoded is represented as 2k bits 301. The data is effectively compressed by performing a logical XOR on neighboring bits to produce compressed data vector 302 having k bits. The compressed data vector 302 is multiplied by a k×[n−k] generation matrix 303 to generate n−k CRC code bits 304. The contents of the generation matrix are understood in the art. Specifically, certain codes are known in the art to be able to produce the contents of generation matrix 303. Such codes include Hamming codes.

A residue is also calculated 305 from the original data 301. In an embodiment, the residue is calculated by dividing the data's value by a number (such as 3) and assigning the remainder as the residue. For example, if data 301 is 16 bits (i.e., k=8), the value of the data may be anywhere between 0 and 65,535. In an embodiment, the value of the data is divided by 3 which will produce a remainder of 0, 1 or 2. The remainder is adopted as the residue 306 for the data 301. In the case where the remainder/residue will always be a 0, 1 or 2, the remainder/residue is of modulo 3 and can be expressed with two bits 306. The output 307 of the encoder as observed in FIG. 3 is composed of the original data 301, the CRC bits 304 and the residue bits 306.

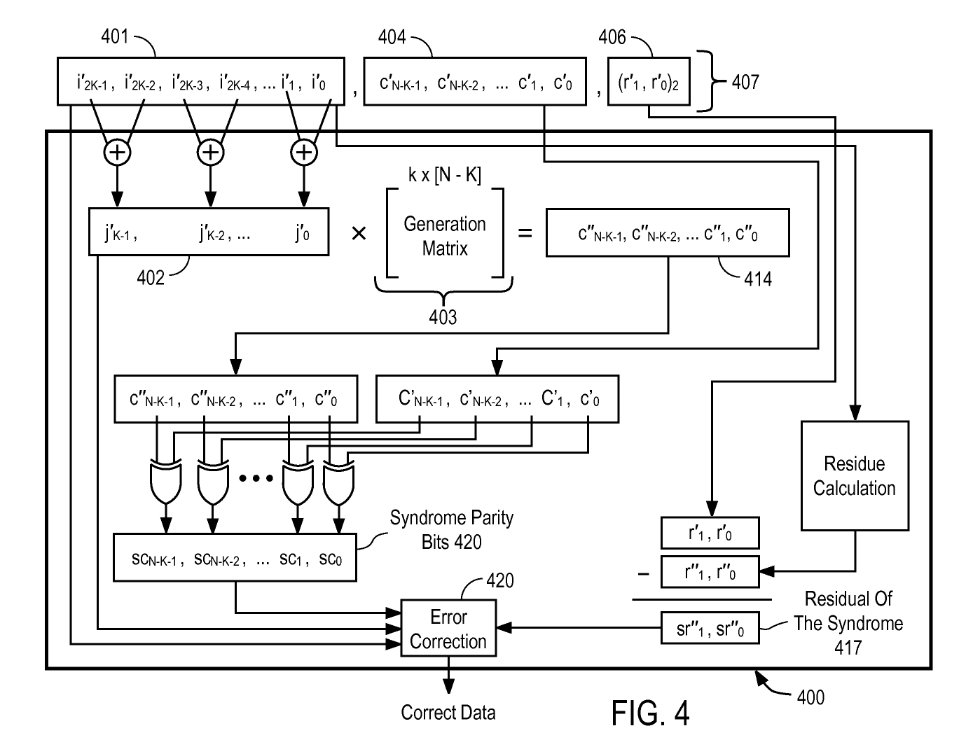

FIG. 4 shows a decoding process 400. According to the decoding process of FIG. 4, the output 307 of the encoder is received as an input, however, because any one of the bits from the encoder output 307 could be flipped en route to the decoder, FIG. 4 labels each bit of the decoder input with a prime. Hence, the decoder input 407 corresponds to received data values 401, received CRC values 404 and received residue 406. According to the decoding process of FIG. 4, the 2k bits of received data 401 is compressed by performing a logical XOR on neighboring bits to produce compressed data vector 402 having k bits. The compressed data vector 402 is multiplied by a k×[n−k] generation matrix 403 to generate n−k CRC values 414. In an embodiment, the generation matrix 403 used by the decoder is the same or is effectively the same as the generation matrix 303 used by the encoder (or at least the mathematical process used to generate CRC values 414 will produce the same CRC results as CRC values 304 if the received data 401 has no errors).

The CRC values 404 received by the decoder are then compared against the CRC values 414 generated by the decoder (e.g., by a logical comparison, such as an XOR, on a bit by bit basis between the two CRC values 404, 414. In an embodiment, a data structure is formed referred to as the “syndrome parity bits” 420. If the syndrome parity bits reveal that the CRC values 404, 414 match (meaning syndrome parity bits are all zero) then the received data is understood to be free of errors. If, however, the syndrome parity bits reveal a mismatch between the CRC values 404, 414, an error may reside in the data and an error correction process 420 begins.

According to an embodiment, an initial phase of the error correction process includes using a CRC error correcting process (any known CRC error correcting process will suffice such as syndrome matching process) to identify which bit in compressed vector 402 differs from a bit in compressed vector 302. Identification of a particular bit location in the compressed vector will implement a plurality of bit locations in the original data 401 owing to the compression. For example, identification of a problem in the jₖ₋₂ bit of the compressed vector 402 implicates one of bits l′₂ₖ₋₃ and l′₂ₖ₋₄ in the received data 401.

A residue value 416 is also calculated from the received data 401 using a mathematical process that produces the same residue result for the same input data as is used in the encoder. For example, in an embodiment, the same residue calculation process is used in both the encoder and decoder (e.g., division by 3). The difference between the residue received by the decoder 406 and the residue calculated by the decoder 416 is calculated (where the construct (r′₁ r′₀)₂ is viewed as a scalar value and the construct (r″₁ r″₀)₂ is viewed as a scalar value). In an embodiment the result 417 is referred to as the “residual of the syndrome”.

The residual of the syndrome is used to correct the error in the received data 401. For example, according to an embodiment where the residual syndrome is two bits (as observed in the embodiments of FIGS. 3 and 4), if the residual of the syndrome is: 1) “01” the error is assumed to be a specific one of the two implicated bits in the received data 401 (e.g., the leftmost/odd bit or the rightmost/even bit); or, 2) “10” the error is assumed to be with the other of the two bits (e.g., the rightmost/even bit or the leftmost/odd bit). For example, continuing with the example above where an error was flagged in either of bits l′₂ₖ₋₃ and l′₂ₖ₋₄, if the residual of the syndrome is: 1) “01” the error is assumed to be a specific one of bits l′₂ₖ₋₃ and l′₂ₖ₋₄, (e.g., bit l′₂ₖ₋₃ or l′₂ₖ₋₄); or, 2) “10” the error is assumed to be with the other of the two bits (e.g., bit l′₂ₖ₋₄ or bit l′₂ₖ₋₃).

In an embodiment, a pre runtime “assumption” is made as to which data bit is flagged as being in error in view of which specific residual of the syndrome value. Notably, in an embodiment, if the error assumption is from a 0 to a 1, the residual of the syndrome 417 is calculated as residue 416—residue 406 in FIG. 4, or, if the error assumption is from a 1 to 0, the residual of the syndrome is calculated as residue 406—residue 416. For example, consider a situation where pre runtime engineering analysis of the design of the data path leading into the decoder reveals a data driver circuit that has a propensity to flip any of the 2k data bits from a 1 to a 0 but not from a 0 to a 1. As such, the residual of the syndrome is calculated as residue 406—residue 416.

With the correct residue calculation, for any pair of data bits flagged to be in error, if the flip of a data bit from a 1 to a 0 in the leftmost/odd position causes the residue of the syndrome to have a value of 10 (when the data bit in the rightmost/even position is not flipped), and, the flip of a data bit from a 1 to a 0 in the rightmost/even position causes the residue of the syndrome to have a value of 01 (when the data bit in the leftmost/odd position is not flipped), then, the correction will be configured to: 1) correct a 0 at the leftmost/odd position to a 1 if the residual of the syndrome value is 10; and, 2) correct a 0 at the rightmost/even position to a 1 if the residual of the syndrome value is a 01.

Contra wise, consider a situation where pre runtime engineering analysis of the design of the data path leading into the decoder reveals a data driver circuit that has a propensity to flip any of the 2k data bits from a 0 to a 1 but not from a 1 to a 0. As such, the residual of the syndrome is calculated as residue 406—residue 416. With the correct residue calculation, for any pair of data bits flagged to be in error, if the flip of a data bit from a 0 to a 1 in the leftmost/odd position causes the residue of the syndrome to have a value of 10 (when the data bit in the rightmost/even position is not flipped), and, the flip of a data bit from a 0 to a 1 in the rightmost/even position causes the residue of the syndrome to have a value of 01 (when the data but in the leftmost/odd position is not flipped), then, the correction part of the ECC algorithm will be configured to: 1) correct a 1 at the leftmost/odd position to a 0 if the residual of the syndrome value is 10; and, 2) correct a 1 at the rightmost/even position to a 0 if the residual of the syndrome value is a 01.

As mentioned above, the specific correction scheme may be worked out pre runtime based on the width of the data bits (2k), the specific manner in which the residue is calculated, the CRC involved and the assumed error based on an analysis of the engineering design. Once determined, the correction algorithm (the specific bit to fix (odd or even), the type of fix (1 to 0 or 1 to 0) and the specific way to calculate the residual of the syndrome) is hardcoded and/or hardwired into the design of the device.

To summarize the above, if the parity syndrome bits do not reveal any error, the received data is accepted as uncorrupted. If the parity syndrome bits indicate the presence of an error in the received data, correction of the compressed vector 402 reveals implicates certain bits in the received data and the residue of the syndrome value is checked. In an embodiment where the residue of the syndrome is modulo 3, a value of 01 identifies one of the implicated bits in the received data, a value of 10 identifies another of the implicated bits in the received data, and, a value of 00 in the residue of the syndrome corresponds to errors in the syndrome parity bits.

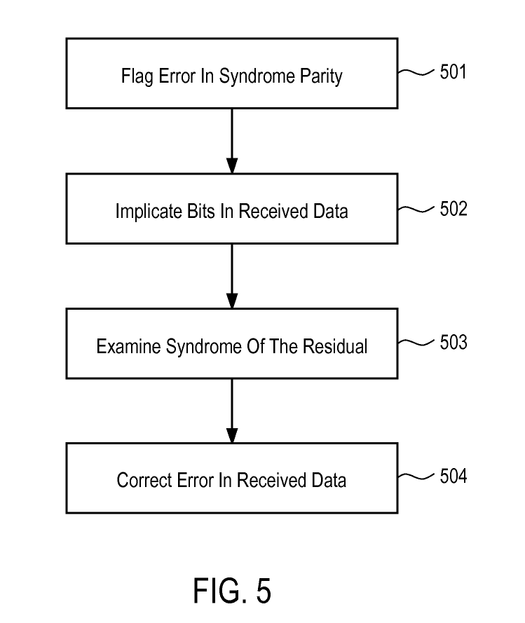

FIG. 5 shows the correction portion of the ECC algorithm as discussed above. According to the process observed in FIG. 5, after the syndrome parity is determined, an error is flagged 501 in the syndrome parity that is used to further flag specific bits in the received data 502. The residual of the syndrome is then examined 503, and, depending on the configuration of the correction algorithm based on the pre-runtime analysis of the device's design, a specific one of the pair of bits is identified as being in error and is flipped to correct the error 504.

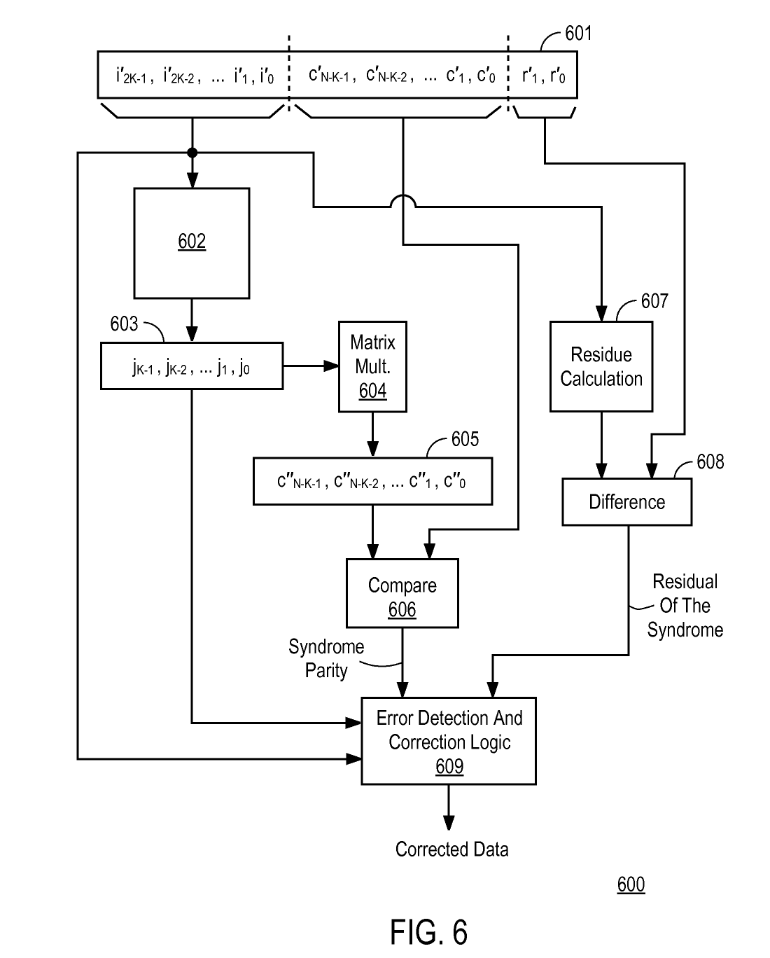

FIG. 6 shows an embodiment of a semiconductor logic chip design 600 that may be used to perform the decoding and error correction process described above. According to the design of FIG. 6, 2k bits worth of data, n−k CRC values and a residue value are entered in input register 601. Logical operation circuitry 602 receives the received data bits and performs a logical operation on them (e.g., a neighboring bit summation) to produce a compressed vector which is entered into register 603. Generation matrix multiplication circuitry 604 performs a matrix multiplication with the compressed vector in register 603 and the numerical values of the generation matrix. The output CRC values are stored in register 605.

A comparator circuit 606 (which, in an embodiment, is implemented as an array of XOR gates) compares the received CRC values in register 601 with the CRC values in register 605. A residue calculation circuit 607 contains logic circuitry that calculates a residue from the received data. A difference circuit 608 calculates a difference between the residue calculated by circuit 607 and the received residue. A detection and correction circuit 609 is constructed with logic circuitry that: i) detects the presence of an error from comparator circuit 606; ii) identifies the implicated bit positions of the received data; and, iii) fixes the appropriate implicated bit of received data based on the value observed at the output of 608. Here, operation of iii) above may be based on a pre-runtime analysis of the expected error (1 to 0) or (0 to 1) and its relationship to the resulting difference in residue values.

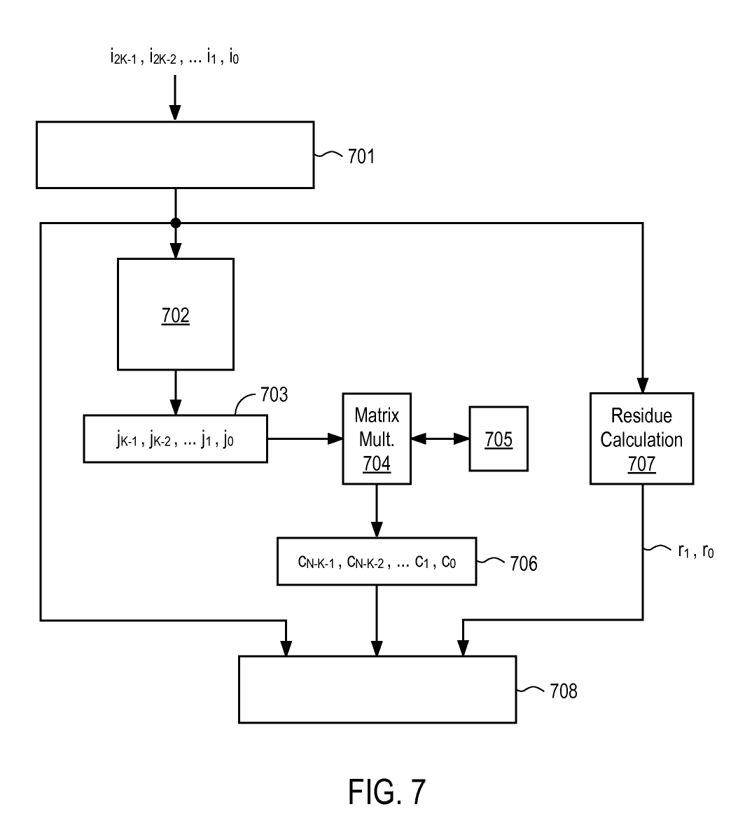

FIG. 7 shows an embodiment of encoder logic circuitry. Data to be encoded is received at input register 701. Logical operation circuitry 702 receives the input data bits and performs a logical operation on them to produce a compressed vector which is entered into register 703. Generation matrix multiplication circuitry 704 has access to a storage medium 705 (e.g., a non volatile storage medium such as a ROM) which contains the numerical values of the generation matrix and performs a matrix multiplication with the compressed vector in register 703 and the numerical values of the generation matrix. The output CRC values are stored in register 706. A residue calculation circuit 707 contains logic circuitry that calculates a residue from the input data. The input data, CRC values and residue are presented in output register 708.

Even though the decoder and encoder are presented above in FIGS. 6 and 7 as being implemented with custom logic circuitry, as alluded to above, any portion of the decoding and encoding functions may be implemented with program code that is processed by semiconductor instruction execution core logic circuitry of some kind.

Processes taught by the discussion above may be performed with program code such as machine-executable instructions that cause a machine such as a semiconductor processing core or microcontroller or other body of electronic circuitry having an instruction execution core of some kind that executes these instructions to perform certain functions. An article of manufacture may be used to store program code. An article of manufacture that stores program code may be embodied as, but is not limited to, one or more memories (e.g., one or more flash memories, random access memories (static, dynamic or other)), optical disks, CD-ROMs, DVD ROMs, EPROMs, EEPROMs, magnetic or optical cards or other type of machine-readable media suitable for storing electronic instructions. Program code may also be downloaded from a remote computer (e.g., a server) to a requesting computer (e.g., a client) by way of data signals embodied in a propagation medium (e.g., via a communication link (e.g., a network connection)).

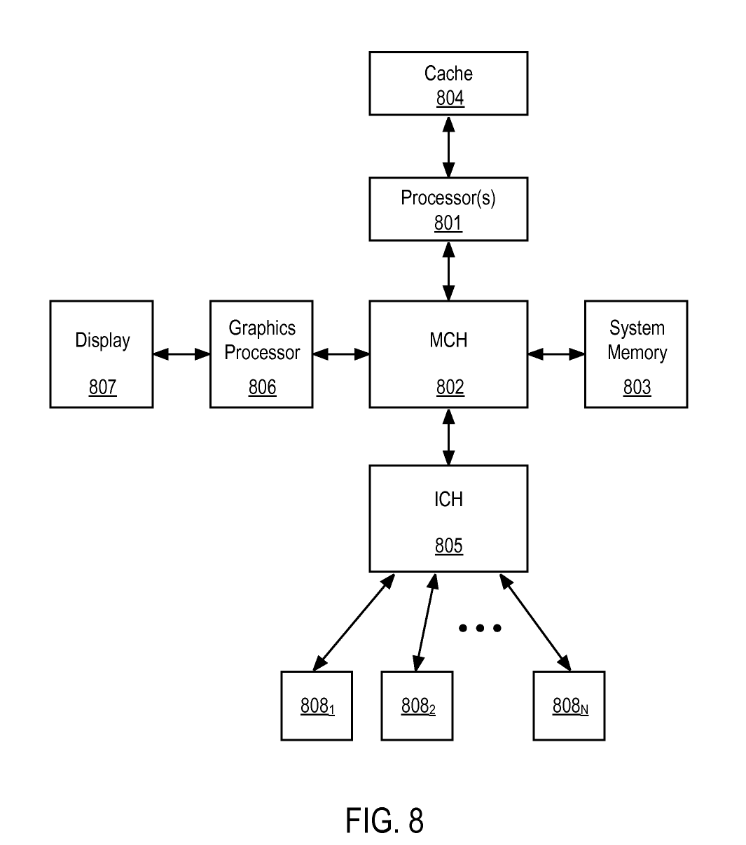

FIG. 8 shows an embodiment of a computing system (e.g., a computer). The exemplary computing system of FIG. 8 includes: 1) one or more processors 801; 2) a memory control hub (MCH) 802; 3) a system memory 803 (of which different types exist such as DDR RAM, EDO RAM, etc,); 4) a cache 804; 5) an I/O control hub (ICH) 805; 6) a graphics processor 806; and 7) a display/screen 807 (of which different types exist such as Cathode Ray Tube (CRT), flat panel, Thin Film Transistor (TFT), Liquid Crystal Display (LCD), DPL, etc.; 8) one or more I/O devices 808.

The one or more processors 801 execute instructions in order to perform whatever software routines the computing system implements. The instructions frequently involve some sort of operation performed upon data. Both data and instructions are stored in system memory 803 and cache 804. Cache 804 is typically designed to have shorter latency times than system memory 803. For example, cache 804 might be integrated onto the same silicon chip(s) as the processor(s) and/or constructed with faster SRAM cells whilst system memory 803 might be constructed with slower DRAM cells. By tending to store more frequently used instructions and data in the cache 804 as opposed to the system memory 803, the overall performance efficiency of the computing system improves.

System memory 803 is deliberately made available to other components within the computing system. For example, the data received from various interfaces to the computing system (e.g., keyboard and mouse, printer port, LAN port, modem port, etc.) or retrieved from an internal storage element of the computing system (e.g., hard disk drive) are often temporarily queued into system memory 803 prior to their being operated upon by the one or more processor(s) 801 in the implementation of a software program. Similarly, data that a software program determines should be sent from the computing system to an outside entity through one of the computing system interfaces, or stored into an internal storage element, is often temporarily queued in system memory 803 prior to its being transmitted or stored.

The ICH 805 is responsible for ensuring that such data is properly passed between the system memory 803 and its appropriate corresponding computing system interface (and internal storage device if the computing system is so designed). The MCH 802 is responsible for managing the various contending requests for system memory 803 access amongst the processor(s) 801, interfaces and internal storage elements that may proximately arise in time with respect to one another.

One or more I/O devices 808 are also implemented in a typical computing system. I/O devices generally are responsible for transferring data to and/or from the computing system (e.g., a networking adapter); or, for large scale non-volatile storage within the computing system (e.g., hard disk drive). ICH 805 has bi-directional point-to-point links between itself and the observed I/O devices 808.

It is believed that processes taught by the discussion above can be practiced within various software environments such as, for example, object-oriented and non-object-oriented programming environments, Java based environments (such as a Java 2 Enterprise Edition (J2EE) environment or environments defined by other releases of the Java standard), or other environments (e.g., a .NET environment, a Windows/NT environment each provided by Microsoft Corporation).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method, comprising:
performing the following with circuitry along a interconnect path on a computing system:
receiving data, CRC values associated with said data and residue information associated with said data;
performing a logical operation on said received data to form a vector of data having less bits than said data;
generating second CRC values from said vector;
comparing said CRC values with said second CRC values and identifying an error in bit locations of said data as a consequence; and,
calculating a second residue from said data and calculating a difference between said residue and said second residue;
using said difference to correct an error in one of said bit locations.

2. The method of claim 1 wherein said generating of said second CRC values includes multiplying said vector with a generation matrix.

3. The method of claim 2 wherein said generation matrix's values are determined with a Hamming code.

4. The method of claim 1 wherein said method is performed at a location along said interconnect path between a memory and an instruction execution core.

5. The method of claim 1 wherein said method if performed at a location along said interconnect path between a cache and an instruction execution core.

6. The method of claim 1 wherein said method is performed at a location along said interconnect path between a memory and a networking interface.

7. The method of claim 1 wherein said method is performed at a location along said interconnect path between a memory and a non volatile storage device.

8. A semiconductor chip having ECC decoder circuitry disposed along any of:
i) a interconnect path that resides between an instruction execution core and a cache;
ii) a interconnect path that resides between an instruction execution core and a memory controller;
iii) an interconnect path that resides between a cache and a memory controller, said ECC decoder circuitry having an input register to receive data, CRC values associated with the data and residue information associated with the data.

9. The semiconductor chip of claim 8 wherein said semiconductor chip further comprises encoder circuitry that produces said encoded data, said CRC values and said residue.

10. The semiconductor chip of claim 8 wherein said ECC decoder comprises a circuit that implements a generation matrix.

11. The semiconductor chip of claim 8 wherein said values of said generation matrix are produced by a Hamming code.

12. The semiconductor chip of claim 8 wherein said ECC decoder is implemented at least partially with program code.

13. The semiconductor chip of claim 8 wherein said ECC decoder circuitry performs the following method:
receiving said data, CRC values and residue information;
performing a logical operation on said data to form a vector of data having less bits than said data;
generating second CRC values from said vector;
comparing said CRC values with said second CRC values and identifying an error in bit locations of said data as a consequence;
calculating a second residue from said data and calculating a difference between said residue and said second residue; and,
using said difference to correct an error in one of said bit locations.

14. A computing system comprising:
a flat panel display;
a semiconductor chip having an instruction execution core, said semiconductor chip having ECC decoder circuitry disposed along any of: i) an interconnect path that resides between an instruction execution core and a cache; ii) an interconnect path that resides between circuitry that prepares data for execution by said instruction execution core and a memory controller; iii) an interconnect path that resides between a cache and a memory controller, said ECC decoder circuitry having an input register to receive data, CRC values associated with the data and residue information associated with the data.

15. The computing system of claim 14 wherein said semiconductor chip further comprises encoder circuitry that produces said encoded data, said CRC values and said residue.

16. The computing system of claim 14 wherein said ECC decoder comprises a circuit that implements a generation matrix.

17. The computing system of claim 14 wherein said values of said generation matrix are produced by a Hamming code.

18. The computing system of claim 14 wherein said ECC decoder is implemented at least partially with program code.

19. The computing system of claim 14 wherein said ECC decoder circuitry performs the following method:
receiving said data, CRC values and residue information;
performing a logical operation on said data to form a vector of data having less bits than said data;
generating second CRC values from said vector;
comparing said CRC values with said second CRC values and identifying an error in bit locations of said data as a consequence;
calculating a second residue from said data and calculating a difference between said residue and said second residue; and,
using said difference to correct an error in one of said bit locations.
